(19) United States
(12) Patent Application Publication
(10) Pub. No.: US 2026/0086462 A1
(43) Pub. Date: Mar. 26, 2026

(54) EXHAUST PIPE SET OF DRYING ROOM FOR SEMICONDUCTORS

(71) Applicant: CHINE YOUNG CO., LTD., HSINCHU CITY (TW)

(72) Inventor: WEI SUNG LEE, HSINCHU CITY (TW)

(21) Appl. No.: 18/897,061

(22) Filed: Sep. 26, 2024

(51) Int. Cl. G03F 7/16

(52) U.S. Cl. CPC G03F 7/168

(57) ABSTRACT

An improved exhaust pipe set of drying room for semiconductors which is installed outside the semiconductor drying room and mainly includes an exhaust vertical pipe combined with multiple sets of exhaust horizontal pipes. A plurality of air guide tubes are provided on the exhaust horizontal pipe, which are connected to one side of the outside of the semiconductor drying room and are communicated with the inside of the semiconductor drying room. The outside of each air guide tube is wrapped with a heating cloth. The inside structure of each tube is made of aluminum alloy and has a built-in film heating sheet, and the outside is covered with a heat insulation board. The tail end of the exhaust horizontal pipe is connected with a set of pipe expansion assembly, and a buffer connection seat is assembled at the bottom of the exhaust vertical pipe.

### FIELD OF THE INVENTION

The present invention relates to an improved technology for the structure of the exhaust pipe set required in the drying room during semiconductors are coated with epoxy resin (photoresist) and then dried.

### BACKGROUND

According to the semiconductor manufacturing process, there is a surface treatment process, such as coating a specific coating, and a drying process must be carried out after coating. This process is to send the semiconductor into a semiconductor drying room equipped with heating equipment for hot air drying. There is a set of exhaust pipes installed outside the semiconductor drying room for exhaust treatment. As shown in FIG. 1, an exhaust pipe set 10 is provided outside one side of the semiconductor drying room 1. The exhaust pipe set 10 mainly consists of an exhaust straight pipe 14 provided with two upper and lower joints 15 to respectively connect an upper exhaust horizontal pipe 12 and a lower exhaust horizontal pipe 13. A plurality of curved pipes 11 are provided on the upper and lower exhaust horizontal pipes 12 and 13, and the curved pipes 11 are connected to the outer side surface of the semiconductor drying room 1 and communicate with the inside of the semiconductor drying room 1. The end of the exhaust straight pipe 14 is connected to an exhaust fan 2.

However, the exhaust gas extracted from the exhaust pipe set 10 is hot gas with a certain high temperature. It is known that when the exhaust gas enters the exhaust horizontal pipes 12 and 13 through the curved pipes 11, the temperature will gradually drop, and crystallization will often occur. This crystal accumulates in the pipes, and over a long period of time, it will cause blockage and exhaust problems. In addition, the exhaust pipe set 10 is usually made of metal, and will expand when heated. Under long-term operation, there may be metal fatigue or overheating and cause structural damage, air leakage or other undesirable results.

### BRIEF DESCRIPTION

The present invention provides an improved exhaust pipe set of drying room for semiconductors. The exhaust equipment is installed outside the semiconductor drying room and mainly includes an exhaust vertical pipe combined with multiple sets of exhaust horizontal pipes. A plurality of air guide tubes provided on the exhaust horizontal pipe are connected to one side of the outside of the semiconductor drying room and are communicated with the inside of the semiconductor drying room. The end of the exhaust vertical pipe is connected to an exhaust fan. The outside of each air guide tube is wrapped with a heating cloth. The inside structure of each tube is made of aluminum alloy and has a built-in film heating sheet, and the outside is covered with a heat insulation board. The tail end of the exhaust horizontal pipe is connected with a set of pipe expansion assembly. A buffer connection seat is assembled at the bottom of the exhaust vertical pipe. This structural design allows the exhaust pipe set to maintain a certain temperature and avoid cooling crystallization obstruction. And when the exhaust horizontal pipe and exhaust vertical pipe expand due to heat, they have a telescopic margin to avoid structural damage.

### BRIEF DESCRIPTION OF THE DRAWINGS

FIG. 1 is a schematic diagram of the conventional exhaust pipe set connected with the semiconductor drying room.

FIG. 2 is a schematic diagram of the exhaust pipe set connected with the semiconductor drying room according to the present invention.

FIG. 3 is a schematic diagram of the cross-sectional structure of the air guide tube of this invention.

FIG. 4 is a schematic diagram of the cross-sectional structure of the exhaust horizontal pipe of this invention.

FIGS. 5 and 6 show structural diagrams of the exhaust horizontal pipe provided with telescopic assembly at the tail end.

FIGS. 7 and 8 show schematic diagrams of the buffer connection seat at the bottom of the exhaust vertical pipe.

### DETAILED DESCRIPTION OF THE INVENTION

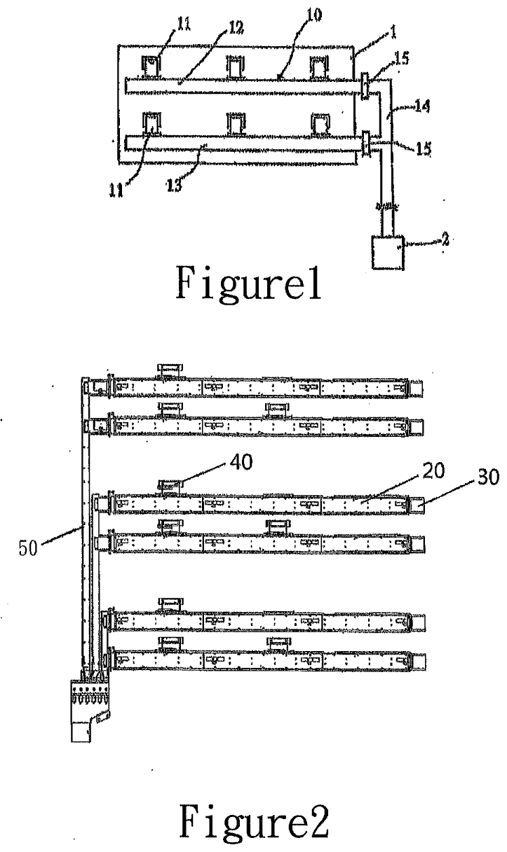

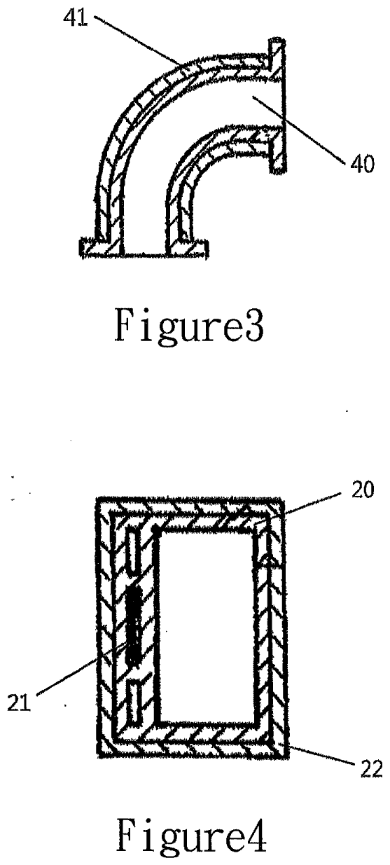

Please refer to FIG. 2 to 4, the present invention mainly includes an exhaust vertical pipe 50 combined with multiple sets of exhaust horizontal pipes 20 connected with several air guide tubes 40, which are arranged on the side of the semiconductor drying room. The outside of each air guide tube 40 is covered with a heating cloth 41, and is respectively connected to the exhaust horizontal pipe 20 to form an internal communication state. Each exhaust horizontal pipe 20 is made of aluminum alloy as the main body, with a film heating sheet 21 built in, and the outside is covered with a heat insulation plate 22. Hence, the exhaust pipe set can maintain the exhaust gas a certain temperature by use of the heating cloth 41 and the film heating sheet 21 and avoid cooling crystallization obstruction The rear end of each exhaust horizontal pipe 20 is connected with a telescopic assembly 30. The bottom of the exhaust vertical pipe 50 is assembled with a buffer connection seat 60.

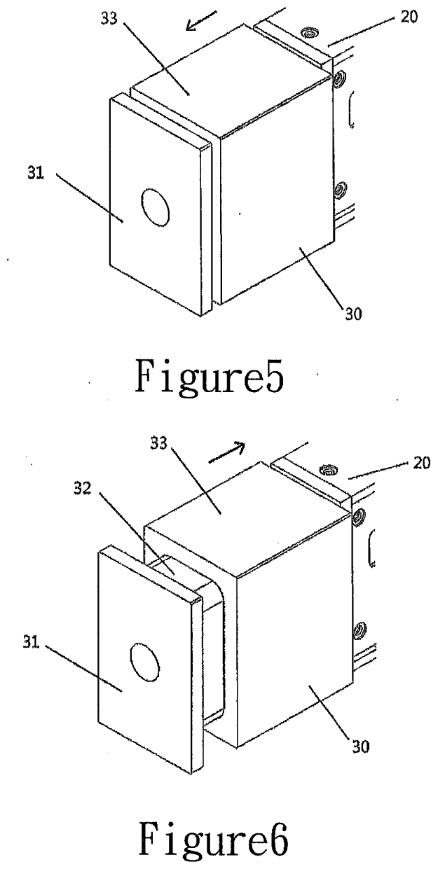

Please refer to FIGS. 5 and 6, the telescopic assembly 30 is connected to the rear end of the exhaust horizontal pipe 20 and has a fixed seat 31 and a sleeve 33. A convex shaft 32 extends from one side of the fixed base 31. The open end of the shaft sleeve 33 is fitted outside the shaft 32 to form a slidable combined state. The other end of the sleeve 33 is connected with the exhaust horizontal pipe 20. Therefore, when the exhaust horizontal pipe 20 is heated and expands, there will be some slight growth that moves the sleeve 33 toward the fixed base 31 (FIG. 5). When the temperature decreases, it moves in the opposite direction (FIG. 6). Therefore, the exhaust horizontal pipe 20 of the present invention can prevent the structure from being damaged due to repeated thermal expansion and contraction.

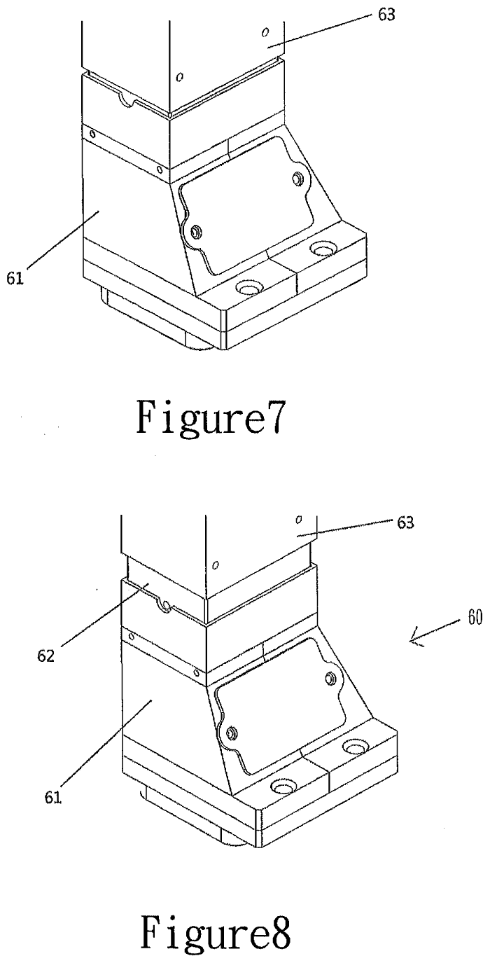

Please refer to FIGS. 7 and 8, the bottom of the exhaust vertical pipe 50 is assembled with a buffer connection seat 60, which includes a base 61. The upper end of the base 61 is provided with a directional column 62. The outside of the directional column 62 is provided with a sliding sleeve 63. The upper part of the sleeve 63 is connected to the lower end of the exhaust vertical pipe 50. When the exhaust vertical pipe 50 expands due to heat and increases in length, it will push the sleeve 63 along the directional column 62 and extend toward the base 61 (FIG. 7), so that the pipe body will not be squeezed. When the temperature decreases, the exhaust vertical pipe 50 shortens due to cooling and returns to its original position (FIG. 8).

In conclusion, the present invention is designed with a structure that can maintain temperature, so that when the extracted exhaust gas passes through the air guide tubes 40, the exhaust horizontal pipes 20, and the exhaust vertical pipe 50, it will not crystallize due to cooling, and can overcome the negative consequences of blockage in the pipes. And the design of the buffer structure can indeed reduce the structural damage of the exhaust pipe set under repeated thermal expansion and contraction operations. Hence, the present invention is quite progressive in this field.

I claim:

1. An improved exhaust pipe set of drying room for semiconductors being installed outside the semiconductor drying room and mainly including an exhaust vertical pipe combined with multiple sets of exhaust horizontal pipes, which includes:
a plurality of air guide tubes connected to one side of the outside of the semiconductor drying room and the outside of each air guide tube wrapped with a heating cloth [symbol]
the aforementioned exhaust horizontal pipes connected to the aforementioned air guide tubes to form an internal communication [symbol] and the main body of each exhaust horizontal pipe being made an aluminum alloy pipe body with a built-in thin film heating plate, and the outside being covered with a heat insulation board.

2. The improved exhaust pipe set of drying room for semiconductors as claimed in claim 1, wherein each exhaust horizontal pipe having the rear end connected to a telescopic assembly, which has a fixed seat and a sleeve [symbol] convex shaft extending from one side of the fixed base and the open end of the shaft sleeve fitted outside the shaft to form a slidable combined state, while the other end of the sleeve connected with the exhaust horizontal pipe.

3. The improved exhaust pipe set of drying room for semiconductors as claimed in claim 1, wherein the bottom of the exhaust vertical pipe assembled with a buffer connection seat including a base, a directional column provided at the upper end of the base, a sliding sleeve provided on the outside of the directional column, and the upper part of the sleeve connected to the lower end of the exhaust vertical pipe.
